(19) United States
(12) Patent Application Publication
(10) Pub. No.: US 2012/0171418 A1
(43) Pub. Date: Jul. 5, 2012

(54) LOW DIELECTRIC CONSTANT NANO-ZEOLITE THIN FILM AND MANUFACTURING METHOD THEREOF

(75) Inventors: Chiung-Fang Lin, Kaohsiung City (TW); Jen-Fang Yu, Taitung County (TW); Shun-Lin Huang, Kaohsiung City (TW)

(73) Assignee: I-SHOU UNIVERSITY, KAOHSIUNG CITY (TW)

(21) Appl. No.: 13/337,328

(22) Filed: Dec. 27, 2011

(30) Foreign Application Priority Data
Dec. 29, 2010 (TW) 99146567

(51) Int. Cl. B32B 3/00; C23C 16/40

(52) U.S. Cl. 428/141; 427/576

(57) ABSTRACT

A fabrication of a low dielectric constant nano-zeolite thin film includes preparing a zeolite nanoparticle suspension that includes zeolite nanoparticles suspended in a solvent and each zeolite nanoparticle includes pores with templating agents disposed inside the pores; performing a heat treatment on a substrate; vaporizing the zeolite nanoparticle suspension to form vaporized droplets containing the zeolite nanoparticles; using a gas to carry the vaporized droplets containing the zeolite nanoparticles into a plasma to perform a plasma reaction; and allowing the plasma-treated zeolite nanoparticles to deposit on the heated substrate to form a nano-zeolite thin film with a dielectric constant less than 2 and the templating agents removed.

### CROSS-REFERENCE TO RELATED APPLICATION

This application claims the priority benefit of Taiwan application serial no. 99146567, filed on Dec. 29, 2010. The entirety of the above-mentioned patent application is hereby incorporated by reference herein and made a part of this specification.

### BACKGROUND OF THE INVENTION

1. Technical Field

The invention relates to a zeolite thin film and a manufacturing method thereof, more particularly to a low dielectric constant nano-zeolite thin film and a manufacturing method thereof.

2. Background

A low dielectric constant material is typically provided to lower the electrical interference between transistors; hence, a closer packing of the transistors is achieved. Ultimately, semiconductor devices that are more compact, have a faster speed and lower power consumption are fabricated. As semiconductor devices continue to miniaturize, a conventional low dielectric constant thin film becomes easily impaired during the high temperature process. Asides from the formation of cracks and damages, it is difficult attaching a conventional low dielectric constant material to a metal layer using as a chip conductive line. Ultimately, problems such as RC delay and cross-talk noise are generated. The traditional low dielectric constant material, for example, silicon dioxide, has a dielectric constant (κ) of about 3.7, which has been determined to be inadequate in fulfilling the next demand in the industry. Accordingly, a material with an even lower dielectric constant must be identified. According to the requirements in the industry, the expected dielectric constant is κ<2.2. Presently, pure silica zeolite has been recognized for its high potential as a low dielectric constant material due to its high porosity, high mechanical strength, good thermal stability.

Generally, the fabrication of a low dielectric constant nano-graded pure silica zeolite thin film applies the in-situ crystallization or spin-coating process. According to the spin-coating method, after a zeolite solution is spin-coated on a substrate, the substrate is heated at a high temperature of 350 to 550° C. to remove the templating agent and the solvent to form a highly porous zeolite thin film. However, the high temperature heating process, not only consumes energy, it easily induces cracks and damages on the surface of the thin film. Hence, the conventional approach in forming a low dielectric constant nano-graded pure silica zeolite thin film is incompatible with the requirements of green chemistry and simple process.

A method of fabricating a low dielectric constant silicon carbide and hydrogen silicon oxycarbide (low-κSiC and H:SiOC) thin film has been proposed by Dow Corning Company. The fabrication method applies plasma-enhanced chemical vapor deposition (PECVD), which is simpler than the above wet methods for film forming. However, the formation of a zeolite thin film requires the preparation of a special formulation of precursor solution and a process of crystallization. Alternatively speaking, zeolite nanoparticles have to be first prepared before the preparation of the thin film. However, for a PECVD process, the nanoparticle solution cannot be pre-prepared. Accordingly, PECVD cannot be directly applied for the fabrication of a zeolite thin film.

The current fabrication methods for a low dielectric constant zeolite thin film not only are complicated, the properties of the thin film need to be improved, for example a further lowering the dielectric constant is required. Further, a templating agent is required as a base for the growth of the zeolite nanoparticles; therefore, the subsequent removal of the templating agent using high temperature heating has to be reconsidered.

### SUMMARY

An exemplary embodiment of the invention provides a fabrication method of a low dielectric constant zeolite thin film, wherein the fabrication method is simpler and eco-friendly, and the resulting thin film has a lower dielectric constant, a higher thermal stability and the zeolite nanoparticles are densely stacked in an organized pattern.

An exemplary embodiment of the invention provides a fabrication method of low dielectric constant zeolite thin film, wherein the method at least includes the following process steps: (A) preparing a zeolite nanoparticle suspension, wherein the zeolite nanoparticle suspension includes a plurality of zeolite nanoparticles suspended in a solvent, for example, an alcohol, and each zeolite nanoparticle includes a plurality of pores with a plurality of templating agents disposed inside the plurality of pores; (B) performing a heat treatment on a substrate; (C) vaporizing the zeolite nanoparticle suspension to form a plurality of vaporized droplets containing the zeolite nanoparticles; (D) using a noble gas to carry the vaporized droplets containing the zeolite nanoparticles into a plasma system to perform a plasma reaction for obtaining of plasma-treated zeolite nanoparticles; and (E) allowing the plasma-treated zeolite nanoparticles to deposit on the heated substrate in step (B) to remove the templating agents of the zeolite nanoparticles to form a low dielectric constant nano-zeolite thin film.

According to an exemplary embodiment of the fabrication method of the invention, a surface modification process is performed after the step of depositing the plurality of plasma treated zeolite nanoparticles on the heated substrate to improve the hydrophobicity of the nano-zeolite thin film.

According to an exemplary embodiment of the fabrication method of the invention, the heat treatment on the substrate is conducted at about 175° C. to 300° C.

According to an exemplary embodiment of the fabrication method of the invention, the dielectric constant of the nano-zeolite thin film is less than 2.

An exemplary embodiment of the invention provides a low dielectric constant nano-zeolite thin film having improved physical properties.

According to an exemplary embodiment of the invention, the low dielectric constant nano-zeolite thin film has a dielectric constant less than 2, the hydrophobicity (CA) of the thin film is greater than 150, the thermal stability of the thin film is about 600° C., and the surface of the low dielectric constant nano-zeolite thin film constituted with zeolite nanoparticles that are densely stacked in an organized terrace-like pattern.

The invention and certain merits provided by the invention can be better understood by way of the following exemplary embodiments and the accompanying drawings, which are not to be construed as limiting the scope of the invention.

### BRIEF DESCRIPTION OF THE DRAWINGS

FIG. 1 is a schematic diagram of an apparatus used in the fabrication of a nano-zeolite thin film according to an exemplary embodiment of the invention.

FIG. 2a illustrates the FTIR spectra of the two nano-zeolite thin films (pl-PSZ) prepared by using two different dispersants, wherein signal (a) is the result of Comparative Example 1a and signal (b) is the result of Exemplary Embodiment 1.

FIG. 2b illustrates the SEM images of the two nano-zeolite thin films (pl-MCM) prepared by using two different dispersants, wherein the image (i) is the result of Exemplary Embodiment 2 and image (ii) is the result of Comparative Example 1b.

FIGS. 3(a), 3(b), 3(c) illustrate the FTIR spectra of (a) silicalite-1, (b) sp-PSZ, and (c) pl-PSZ, respectively.

FIG. 4a illustrates the FTIR spectra of pl-MCM before the surface modification process (a) and pl-MCM after the surface treatment process (b).

FIG. 4b illustrates C-13 NMR spectra of sp-MCM thin film formed without calcination (a), a pl-MCM film formed according to Exemplary Embodiment 2, in which the substrate is heated at 175° C. for 10 minutes (b), and a sp-MCM film formed with calcination at 500° C. for 4

hours.

FIG. 5a is an IR spectrum of the MCM-41 zeolite thin film (pl-MCM) formed according to the fabrication method of the invention.

FIG. 5b illustrates an IR spectrum of a MCM-41 zeolite thin film (sp-MCM) formed according to the conventional approach and after calcination at about 500° C. for 4 hours.

FIG. 5c illustrates an IR spectrum of a MCM-41 zeolite thin film (sp-MCM) formed according to the conventional approach and after calcination at about 200° C. for 4 hours.

FIG. 6 illustrates a SEM image of pl-PSZ at a magnification of 2000×.

FIG. 7 illustrates a SEM image of pl-PSZ at a magnification of 100000×

FIG. 8 illustrates a SEM image of sp-PSZ at a magnification of 250×.

FIG. 9 illustrates a SEM image of sp-PSZ at a magnification of 100000×.

FIG. 10a-10c illustrate SEM images of sp-MCM after calcination at 500° C. at a magnification of 2000× (FIG. 10a), 10000× (FIGS. 10b), and 100000× (FIG. 10c), respectively.

FIGS. 11a and 11b illustrate SEM images of pl-MCM at a magnification of 2000× and 100000×, respectively.

FIG. 12 illustrate SEM images of the cross-section of pl-PSZ during various time intervals (a) 5 minutes (b) 15 minutes (c) 30 minutes (d) 60 minutes of the deposition.

FIG. 13 illustrates a SEM image of the cross section of the pl-MCM zeolite thin film fabricated according to Exemplary embodiment 2

FIG. 14 illustrates a SEM image of the cross section of the multi-layer sp-PSZ fabricated according to Comparative Example 1.

FIG. 15 illustrates the contact angel formed when a liquid droplet of glycerin is dispensed on the surface of the pl-PSZ thin film.

FIG. 16 illustrates the contact angel formed when a liquid droplet of glycerin is dispensed on the surface of the sp-PSZ.

FIG. 17 illustrates the contact angel formed when a liquid droplet of glycerin is dispensed on the surface of the pl-MCM thin film.

FIG. 18 illustrates the IR spectra of pl-PSZ and silicalite-1 powders at various temperatures.

FIG. 19 illustrates the IR spectra of pl-MCM and silicalite-1 powders at various temperatures.

FIG. 20 illustrates the IR spectra of a pl-PSZ film and a sp-PSZ film at various temperatures.

FIG. 21 depicts the dielectric constant results of, pl-PSZ (a), and pl-MCM (b).

### DETAILED DESCRIPTION OF DISCLOSED EMBODIMENTS

In the following disclosure, the fabrication method of a low dielectric constant nano-zeolite thin film is exemplified by the fabrication of a microporous silicalite-1 material and a mesoporous MCM-41 material. However, it is to be understood that these exemplary embodiments are presented by way of example and not by way of limitation. For example, the fabrication method of the invention is applicable to the fabrication a zeolite nanoparticle material with a wide range of pore sizes.

In one embodiment of the invention, the preparation of a zeolite nanoparticle suspension in step (A) above is exemplified by the preparation of a silicalite-1 zeolite nanoparticle suspension. The silicalite-1 nanoparticle suspension may be formed according to a conventional method as proposed by the team of Johan A. Martens (Salvador Eslava, Christine E. A. Kirschhock, StelianaAldea, Mikhail R. Baklanov, Francesca Iacopi, Karen Maex, Johan A. Martens, “Characterization of spin-on zeolite films prepared from Silicalite-1 nanoparticle suspensions”, Microporous and Mesoporous Materials, vol. 118, pp. 458-466, 2009). The silicalite-1 nanoparticle suspension is prepared from a precursor solution with the molar composition of 25 TEOS (tetraethyl orthosilicate): 9 TPAOH (tetrapropylammonium hydroxide): 360 water: 200 ethanol (EtOH), wherein TEOS, TPAOH (serving a template molecule), water and ethanol are mixed, reacted and purified, followed by a further addition of ethanol.

In another exemplary embodiment, the preparation of a zeolite nanoparticle suspension in step (A) above is exemplified by the preparation of a MCM-41 nanoparticle suspension. The preparation of a MCM-41 zeolite nanoparticle suspension is achieved, for example, according to a method developed by the team of Hiroaki Keisei Suzuki, Kenichi Ikari, and Hiroaki Imai* “Synthesis of Silica Nanoparticles Having a Well-Ordered Mesostructure Using a Double Surfactant System” J. AM. CHEM. SOC., vol. 126, 462-463,2004). The MCM-41 nanoparticle suspension is prepared from a precursor solution with the molar composition of 0.52M TEOS: 0.25 M CTAC (cetyltrimethylammonium chloride): 4.9 mM F-127 (Pluronic® F127, a non-ionic surfactant poloxamer with a molecular weight of approximately 12,500 daltons): 1.54 M NH₄OH, wherein TEOS, CTAC, F-127 and ammonia are mixed, reacted, and purified.

In an exemplary embodiment, the heat treatment of the substrate in step (B) is conducted at a temperature range of 175° C. to 300° C. When the substrate is heated to a temperature above 300° C., the structure of the zeolite nanoparticles is damaged.

In one exemplary embodiment, prior to the substrate heat treatment in step (B) a pre-treatment step is performed to enhance the subsequent thin film formation.

In one exemplary embodiment, the zeolite nanoparticle suspension is vaporized in step (C) using a vaporizer. The vaporizer is, for example, an ultrasonic atomizer. In this exemplary embodiment, vaporizing the zeolite nanoparticle suspension results in the formation for a plurality of vaporized droplets containing the zeolite nanoparticles. Further, by controlling the strength of the vaporizer, the vaporized droplets are substantially uniform in size.

The plasma reaction of step (D) is achieved by passing a plasma under atmospheric pressure, for example, using an atmospheric plasma system. In one exemplary embodiment, the plasma in step (D) is generated by applying a voltage of 60V to 90 V. In another exemplary embodiment, the plasma in step (D) is generated by applying a pulse type alternating current voltage of 60V to 90V. Theoretically speaking, the higher the voltage, the film-forming effect through the deposition of the zeolite nanoparticles is better. However, when the plasma voltage is higher than 90V, voltaic arc phenomenon may occur.

The noble gas in step (D) is, for example, argon gas, and the argon gas is provided at a gas flow rate between 6 to 50 L/m (slm), for example. In yet another exemplary embodiment, the argon gas is provided at 10 L/m (slm).

The flow rate of the vaporized droplets containing the zeolite nanoparticles in step (D) ranges from 60 to 20 cc/min (sccm), for example. In one exemplary embodiment, the flow rate of the vaporized droplets containing the zeolite nanoparticles is about 100 cc/min.

In one exemplary embodiment, the low dielectric constant nano-zeolite thin film fabricated in step (E) is lower than 2.

In one exemplary embodiment, the low dielectric constant nano-zeolite thin film fabricated in step (E) is lower than 1.95.

In one exemplary embodiment, the low dielectric constant nano-zeolite thin film fabricated in step (E) is about 80 nm to about 1000 nm thick.

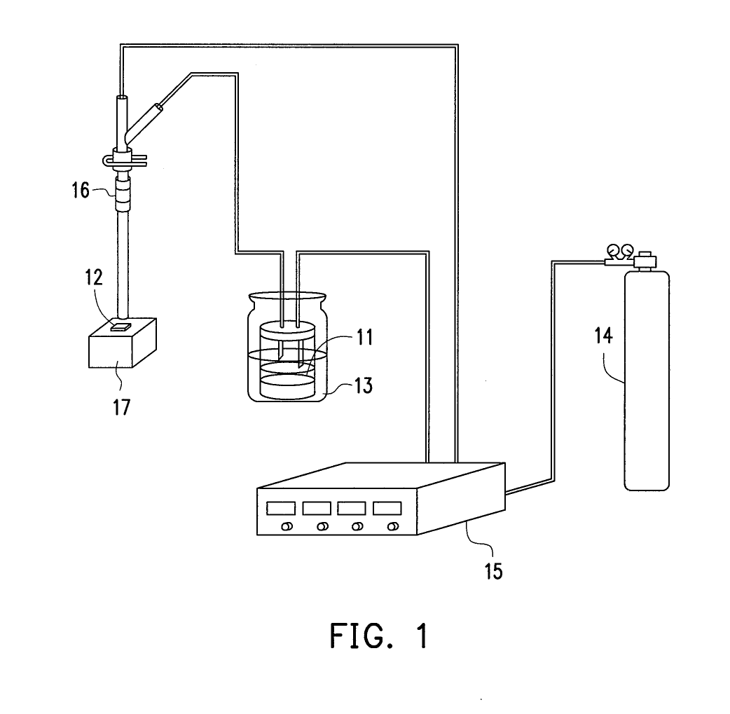

In one exemplary embodiment, the apparatus used in the fabrication of a nano-zeolite thin film is as shown in FIG. 1. The apparatus includes, for example, a zeolite nanoparticle suspension 11, a substrate 12, an ultrasonic atomizer 13, a noble gas 14, a flow rate controller 15, a plasma generator 16, and a heater 17. In one exemplary embodiment of the fabrication method of a nano-zeolite thin film of the invention, (a) the zeolite nanoparticle suspension 11 is first prepared; (b) the substrate 12 is placed on a heater 17 and a heat treatment is performed on the substrate 12; (c) using an ultrasonic atomizer 13, the zeolite nanoparticle suspension 11 is vaporized to form a plurality of vaporized droplets containing the zeolite nanoparticles; (d) using a flow rate controller 15, the vaporized droplets containing zeolite nanoparticles are delivered into a plasma generator 16, and a plasma reaction is performed to obtain a plurality of plasma-treated zeolite nanoparticles; and (e) the plasma-treated zeolite nanoparticles are then deposited on the substrate 12 heated in step (b) to obtain a low dielectric constant nano-zeolite thin film.

In one exemplary embodiment, in the above step (e), the distance between the outlet of the plasma generator 16 and the substrate 12 is about 3 to 5 mm. When the distance is less than 3 mm, it has been determined that the voltaic arc phenomenon may occur. In one exemplary embodiment, the distance is about 5 mm.

According to the exemplary embodiments, the fabrication method of a nano-zeolite thin film of the invention is a dry method. By vaporizing a zeolite nanoparticle suspension to form a plurality of vaporized droplets containing the zeolite nanoparticles, a plasma process can be applied. Hence, the fabrication method of a nano-zeolite thin film of the invention is much simpler. Moreover, by adjusting the time and the conditions of the process steps, and by using plasma and heat treatment on the substrate, the solvent and the templating agent are removed to form a more densely packed and evenly stacked zeolite nanoparticles. Accordingly, a nano-zeolite thin film, with desirable film quality and precluded from cracks and damages, is formed.

The fabrication method of a nano-zeolite thin film is further exemplified with the following exemplary embodiments. It is to be understood these exemplary embodiments are presented by way of example and not by way of limitation.

### Exemplary Embodiment 1

### Formation of Silicalite-1 Nanoparticle Suspension

The molar composition of the silicalite-1 nanoparticle suspension is 25 TEOS (tetraethyl orthosilicate): 9 TPAOH (tetrapropylammonium hydroxide): 360 water: 200 EtOH. TEOS with 98% purity is purchased from ACROS company, which conforms to the purity requirement of silicon source demanded by the semiconductor industry. TPAOH with 40% purity is purchased from Alfa Aesar.

Based on the above molar ratio, an appropriate amount of TPAOH and deionized water are evenly mixed and stirred for 15 minutes. An appropriate amount of ethanol is then added and mixed for 5 minutes, followed by dropwise addition of TEOS. The reaction mixture is then stirred vigorously for 72 hours, followed by heating in an autoclave at 90° C. for 68 hours and natural cooling. The zeolite nanoparticle suspension 11 is obtained after centrifugation at 13000 rpm.

### Characterization of Silicalite-1 Nanoparticles

The structure of the zeolite nanoparticles is characterized by X-ray diffraction (XRD) (X'PERT Pro, PANalytical), Fourier transform infrared spectroscopy (FT-IR) (Nicolet 5700, ThermoNICOLET), and field emission-scanning electron microscopy (FE-SEM) (Hitachi-4700, Hitachi). The results of these studies confirm that the zeolite nanoparticles contained in the above zeolite nanoparticle suspension 11 includes MFI-type pure silica zeolite (silicalite-1). The resulting zeolite nanoparticles appear to have a substantially uniform hexagonal morphology, with a particle diameter of about 50 nm.

### Pre-treatment of the Substrate

An ITO (indium titanium oxide) glass plate, which is an electrical conductor, is ultrasonically vibrated in soap water for about 15 minutes, washed copiously with deionized water, ultrasonically vibrated in acetone for 15 minutes, and washed copiously again with deionized water. The ITO glass plate is then immersed in ethanol and vibrated for 15 minutes, followed by drying in room temperature.

### Preparation of Silicalite-1 Thin Film

The ITO glass substrate 12 is heated to 300° C. and then placed in the apparatus as shown in FIG. 1. The above zeolite nanoparticle suspension 11 is vaporized to form a plurality of vaporized droplets containing zeolite nanoparticles. The zeolite nanoparticle suspension 11 is vaporized using the ultrasonic atomizer 13 and a dispersant. The dispersant may include, for example, a solvent, such as alcohol, acetone, acetonenitrile, water, alcohol and water mixture, etc. In this exemplary embodiment, the dispersant is ethanol. Thereafter, a noble gas 14, for example, a combination of an argon gas and an oxygen gas, is used to carry the vaporized droplets containing zeolite nanoparticles into a plasma generator 16 to perform a plasma reaction. The flow rate controller 15 controls the flow rate of the gases to about 10 L/min (slm), for example, and the flow rate of the vaporized droplets containing zeolite nanoparticles to about 100 cc/min, for example. The plasma generator 16 is set at a voltage of about 90V, and the distance between the outlet of the plasma generator 16 and the substrate 12 is adjusted to about 5 mm. The plasma treated zeolite nanoparticles are then deposited on the heated substrate 12, wherein the templating agent of the zeolite nanoparticles is removed during the deposition process and a nano-zeolite thin film is formed.

### Exemplary Embodiment 2

### Formation of MCM-41 Zeolite Nanoparticle Suspension

The preparation of a MCM-41 zeolite nanoparticle suspension is achieved according to a conventional method as developed by the team of Hiroaki in 2005. The MCM-41 zeolite nanoparticle suspension is prepared from a precursor solution with the molar composition of 0.52M TEOS: 0.25 M CTAC (cetyltrimethylammoniumchloride): 4.9 mM F-127 (Pluronic® F127 is a non-ionic surfactant poloxamer with a molecular weight of approximately 12,500 daltons): 1.54 M NH₄OH, wherein 30 gm of hydrochloric acid (HCl) with a pH=0.5 and 3.5 gm of TEOS are mixed and stirred for 20 minutes, followed by adding 2.6 gm of CATC and 2.0 gm of F-127 at room temperature and stirring for 3 hours. 3.0 gm of ammonia is further added at room temperature and the reaction mixture is stirred by 24 hours. A zeolite nanoparticle suspension is obtained after centrifugal filtering with deionized water for three times.

### Characterization of MCM-41 Zeolite Nanoparticles

The structure of the MCM-41 zeolite nanoparticles is characterized by X-ray diffraction (XRD), scanning electron microscopy, transmission electron microscopy (TEM), etc. The XRD pattern reveals the characteristic peaks of MCM-41 zeolite nanoparticles. The observations based on TEM and SEM at different magnifications reveal the existence of a highly ordered array structure of uniform-sized hexagonal pore channels. The particle diameter is determined to be about 60 nm.

### Pre-Treatment of the Substrate

Similar to Exemplary embodiment 1, an ITO (indium titanium oxide) conductive glass plate is used as the substrate and the pre-treatment of the ITO (indium titanium oxide) conductive glass plate is similar to the pre-treatment process discussed above.

### Preparation of MCM-41 Zeolite Thin Film

The preparation of a MCM-41 zeolite thin film is similar to the preparation of a silicalite thin film, in which the ITO glass substrate 12 is first heated to 175° C., followed by placing the substrate 12 in the apparatus as shown in FIG. 1. The zeolite nanoparticle suspension 11 (the MCM-41 zeolite nanoparticle suspension) is vaporized, using the ultrasonic atomizer 13 and water as a dispersant,to form a plurality of vaporized droplets containing zeolite nanoparticles. The vaporized droplets containing zeolite nanoparticles are then delivered to the plasma generator 16 via the noble gas 14, at which a plasma reaction is conducted. The flow rate condition, controlled by the flow rate controller 15, of the gases and the vaporized droplets containing zeolite nanoparticles are similar to those in the first exemplary embodiment. Similarly, the plasma generator 16 is set at a voltage of about 90V, and the distance between the outlet of the plasma generator 16 and the substrate 12 is adjusted to about 5 mm. The plasma treated MCM-41 zeolite nanoparticles are then deposited on the heated substrate 12, wherein the templating agent of the MCM-41 zeolite nanoparticles is removed during the deposition process and a nano-zeolite thin film is formed.

### Surface Modification of the MCM-41 Zeolite Thin Film

The fabrication of a MCM-41 zeolite thin film further includes a surface modification step subsequent to the initial formation of the MCM-41 zeolite thin film. In this exemplary embodiment, the substrate with the MCM-41 zeolite thin film deposited thereon is immersed in trimethylchlorosilane (TMCS). Thereafter, the thin film is heated under 60° C. for about 15 minutes to remove any excess and un-bonded TMCS. The surface modification step modifies the hydrophilic surface with the excess OH groups of the initial MCM-41 zeolite thin film to a form a hydrophobic MCM-41 zeolite thin film.

### COMPARATIVE EXAMPLE 1a

The formation of the zeolite nanoparticle suspension and the treatment method of the substrate in comparative example 1a are similar to those in Exemplary embodiment 1. The system used in forming the zeolite thin film of Comparative example 1 is similar to the system as shown in FIG. 1. The only difference lies in the type of dispersant used for vaporizing the zeolite nanoparticle suspension 11 in forming a plurality of vaporized droplets containing zeolite nanoparticles. In the Comparative example 1a, the dispersant is water. The setting parameters of the plasma system are similar to those in Exemplary embodiment 1, and a zeolite nanoparticle thin film of Comparative Example 1a is obtained after the plasma-treated zeolite nanoparticles are deposited on the heated substrate 12.

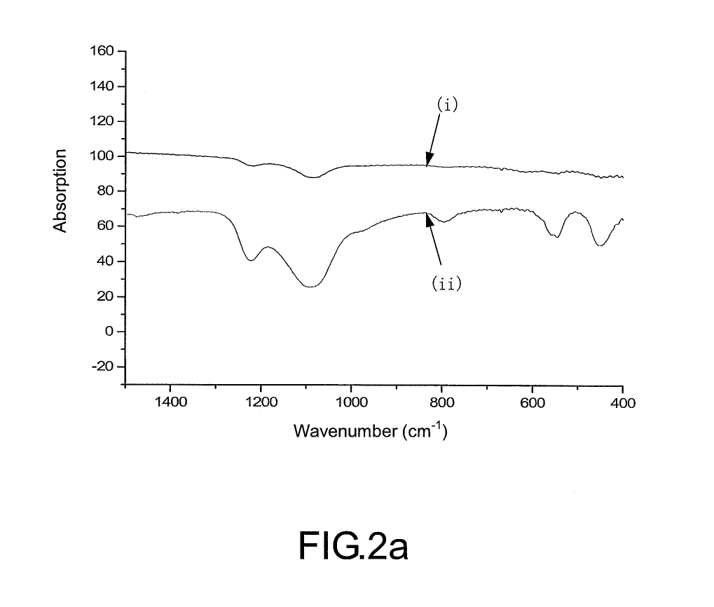

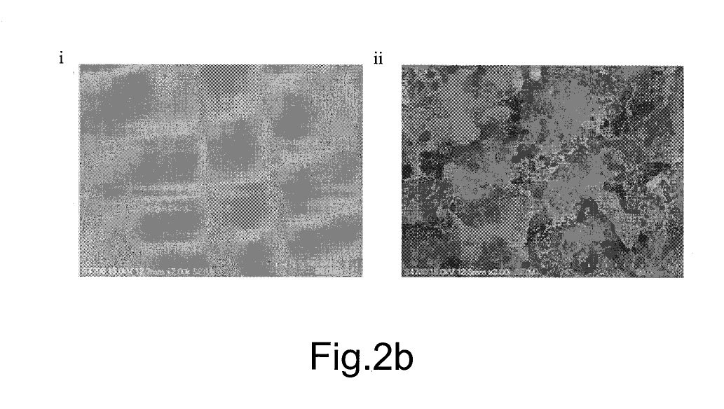

The IR spectra of the two nano-zeolite thin films prepared by using two different dispersants [signal (i) is the result of Comparative Example 1a, signal (ii) is the result of Exemplary Embodiment 1] is illustrated in FIG. 2a. The IR signal of the nano-zeolite thin film formed by using water as a dispersant to vaporize the zeolite nanoparticle suspension is significantly weaker. According to the IR results, a film is not easily formed by using water as a dispersant of the silicalite-1 nanoparticle suspension. Instead, the film-forming effect is better by using alcohol, such as ethanol, as a dispersant of the silicalite-1 nanoparticle suspension.

### COMPARATIVE EXAMPLE 1b

The formation of the zeolite nanoparticle suspension and the treatment method of the substrate in comparative example 1 are similar to those in Exemplary embodiment 2 (MCM-41 zeolite nanoparticle suspension). The system used in forming the zeolite thin film of Comparative example 1b is similar to the system as shown in FIG. 2. The only difference lies in the type of dispersant used for vaporizing the zeolite nanoparticle suspension 11 in forming a plurality of vaporized droplets containing zeolite nanoparaticles. In the Comparative example, the dispersant is ethanol. The setting parameters of the plasma system are similar to those in Exemplary embodiment 1, and a nano-zeolite thin film of Comparative Example 1b is obtained after the plasma-treated zeolite nanoparticles are deposited on the heated substrate 12.

FIG. 2b illustrates the SEM images of the two nano-zeolite thin films (Pl-MCM) prepared by using two different dispersants, wherein in image (i) is the result of Exemplary Embodiment 2 and image (ii) is the result of Comparative Example 1b.

### COMPARATIVE EXAMPLE 2 AND COMPARATIVE EXAMPLE 3

The formation of the zeolite nanoparticle suspension and the treatment method of the substrate in Comparative Example 2 and Comparative Example 3 are respectively similar to those in Exemplary embodiment 1 and Exemplary embodiment 2. The only difference lies in the film forming method. The zeolite thin films in the Comparative Examples 2 and 3 are fabricated by the spin-coating method, in which a substrate is disposed on a spin-coating machine, and the zeolite nanoparticle suspension is spin-coated on the substrate twice (each time being 90 seconds and the rotational speeds respectively being 200 rpm and 400 rpm). After the spin-coating process, the substrate with the zeolite nanoparticle suspension coated thereon is placed in an oven at 60° C. to heat dry the surface moisture and to form a nano-zeolite thin film on the substrate.

### Characterization of Nano-Zeolite Thin Films

To verify the differences in properties between the nano-zeolite thin films (hereinafter “pl-PSZ” and “pl-MCM”) formed according to the fabrication method of a low dielectric constant nano-zeolite thin film in Exemplary Embodiments 1 and 2, respectively, and the nano-zeolite thin films (hereinafter “sp-PSZ” and “sp-MCM”) formed according the spin coating method respectively in Comparative Example 2 and Comparative Example 3, various analyses were performed on the as-prepared nano-zeolite thin films.

### Structure Analysis

Fourier transform infrared (FTIR) spectroscopy (Nicolet 5700, Thermo NICOLET,) was used to identify the functional groups of the zeolite molecules in the zeolite nanoparticle suspension (hereinafter “silicalite-1), pl-PSZ, pl-MCM and sp-PSZ.

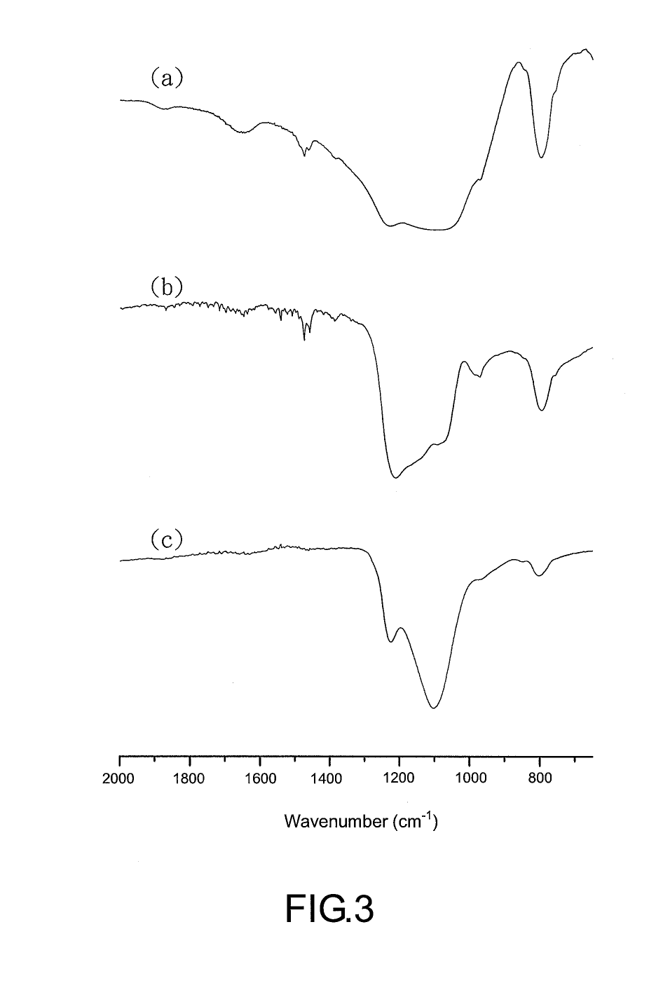

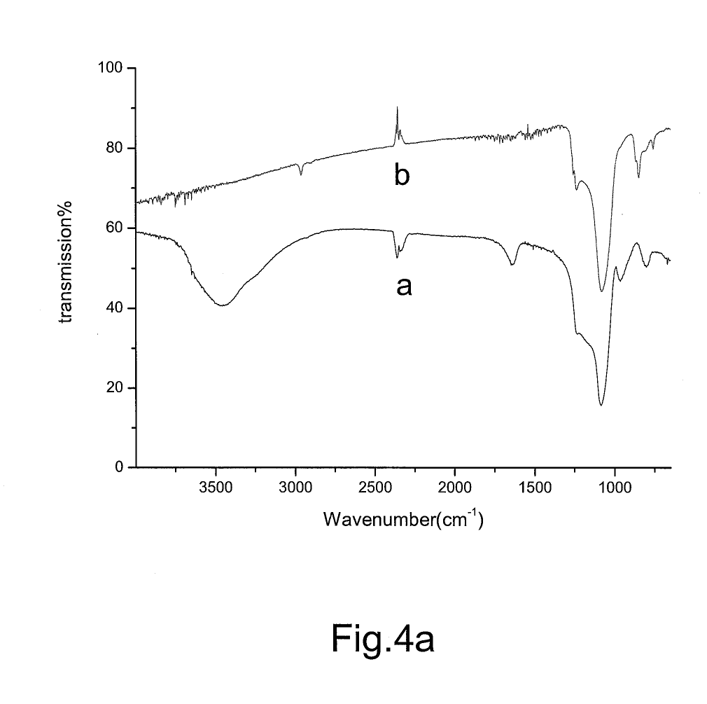

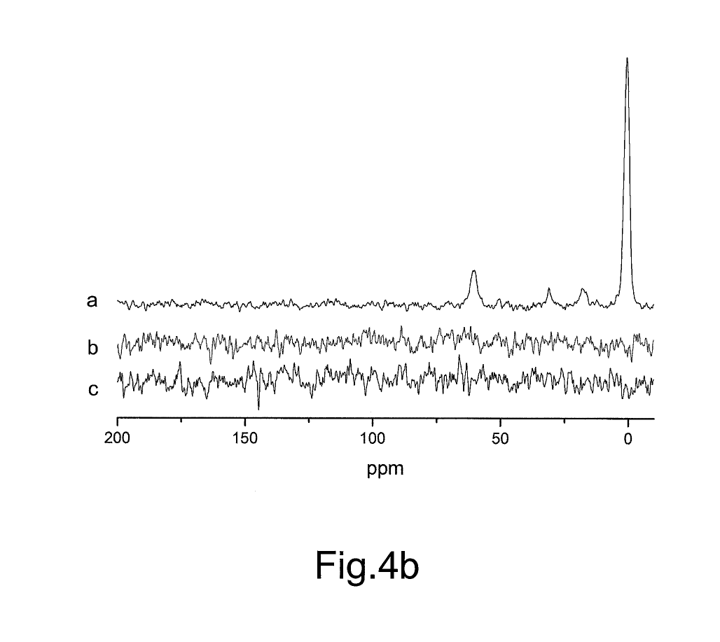

The FTIR spectra of (a) silicalite-1, (b) sp-PSZ, and (c) pl-PSZ are respectively shown in FIGS. 3(a), 3(b), 3(c). The FTIR spectra of pl-MCM before the surface modification process (a) and pl-MCM after the surface modification process (b) arerespectively shown in FIG. 4a. As shown in FIGS. 3(a) and 3(b), the spectra of silicalite-1 and sp-PSZ exhibit the characteristic absorption band of the template molecules TPA at around 1400-1500 cm⁻¹, while the same absorption band is not observed for the spectrum of pl-PSZ as shown in of FIG. 3(c), indicating the fabrication method of the nano-zeolite thin films of the invention effectively removes the TPA template molecules. The spectrum of sp-PSZ exhibits an absorption band at 950 and 1470 cm⁻¹, attributable to the SiOH and OH groups. These two function groups may arise from ethanol or the functional groups carried in the pores of the zeolite; on the other hand, the same absorption band is not observed for pl-PSZ, confirming that the fabrication method of the invention effectively removes the SiOH and OH function groups originated from ethanol and the pores of the zeolite.

The spectrum of the pl-MCM before the surface treatment process (signal (a) in FIG. 4a) exhibits two distinct absorption bands at 3500 cm⁻¹ and 962 cm⁻¹ attributable to the OH groups, in which they disappear in the spectrum of the pl-MCM after the surface treatment process (signal (b) in FIG. 4a). Instead, the absorptions at 2964 cm⁻¹ and 846 cm⁻¹ become visible due to the vibration modes of O—Si—CH₃ and —Si(CH₃)₃, respectively. The IR results suggest the excess OH groups on the surface of the MCM-41 thin film are replaced by methanol groups through trimethylcholorsilane (TMCS) after the surface modification process to become a hydrophobic thin film.

FIG. 4b is a C-13 NMR spectra of sp-MCM thin film formed without calcination (a), a pl-MCM film formed according to Exemplary Embodiment 2, in which the substrate is heated at 175° C. for 10 minutes (b), and a sp-MCM film formed with calcination at 500° C. for 4 hours. The results indicate that the template molecules are removed from the zeolite film according to the fabrication method of the invention using a plasma method and the conventional spin-coating method with a calcination process conducted at an elevated temperature.

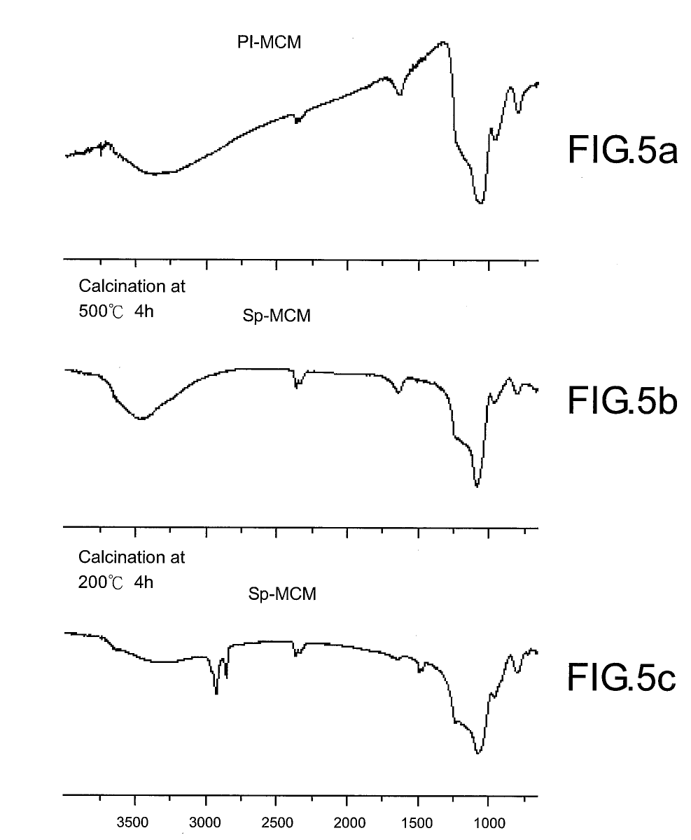

Moreover, the template molecules in the MCM-41 zeolite thin film (pl-MCM) formed according to the fabrication method of the invention can also be effectively removed. Referring to FIGS. 5a, in the spectrum of the MCM-41 zeolite thin film (pl-MCM) formed according to the fabrication method of the invention, the two absorption bands at 2800-2900 cm⁻¹ and the one at 1475 cm⁻¹ are nearly invisible confirming that the template molecules have been completely removed. The spectrum of a MCM-41 zeolite thin film (sp-MCM), as shown in FIG. 5b, formed according to the conventional approach indicates that the template molecules are removed after calcination at about 500° C. for 4 hours. The spectrum of a MCM-41 zeolite thin film (sp-MCM), as shown in FIG. 5c, formed according to the conventional approach exhibits the two distinct absorption bands at 2800-2900 cm⁻¹ and the one at 1475 cm⁻¹ after calcination at about 200° C. for 4 hours, indicating the template molecules can not be removed at 200° C.

### Surface Morphology

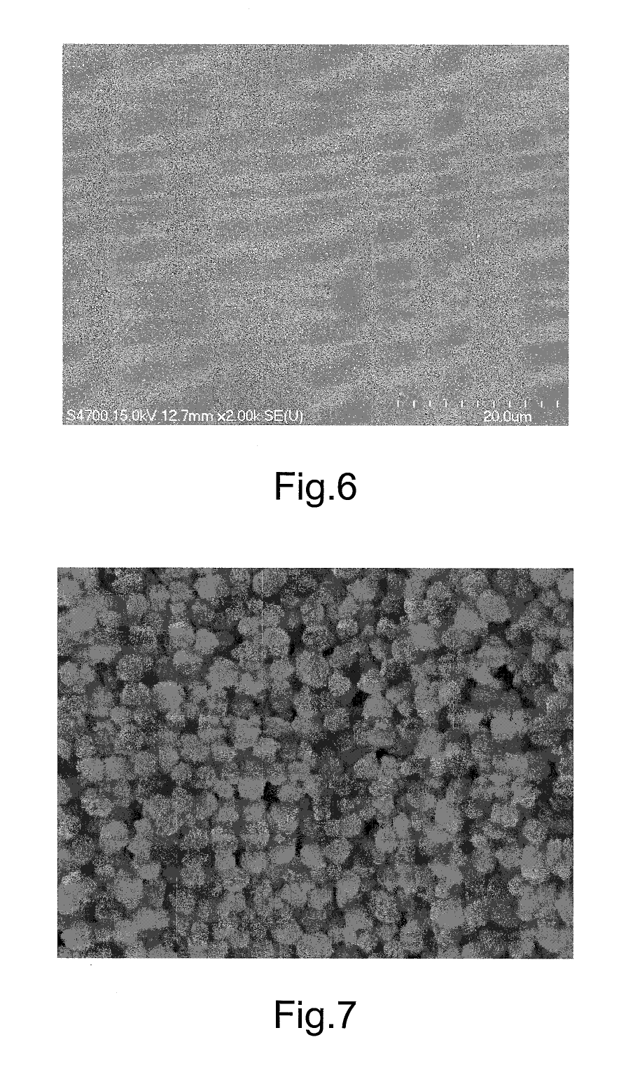

The surface morphology of the sp-PSZ and pl-PSZ nano-zeolite thin films is analyzed by field emission-scanning electron microscopy (FE-SEM) (S-4700, Hitachi) and the results are shown in FIGS. 6-9.

As shown in FIG. 6, the SEM image of pl-PSZ at a magnification of 2000× reveals a dense packing surface. When the magnification is increased to 100000× as shown in FIG. 7, it can be observed that the nano-zeolite thin film surface is constituted with zeolite nanoparticles with an average nanoparticle size of about 50 nm. The surface topography is uneven, but the surface structure of zeolite particles is stacked in an organized terrace-like pattern.

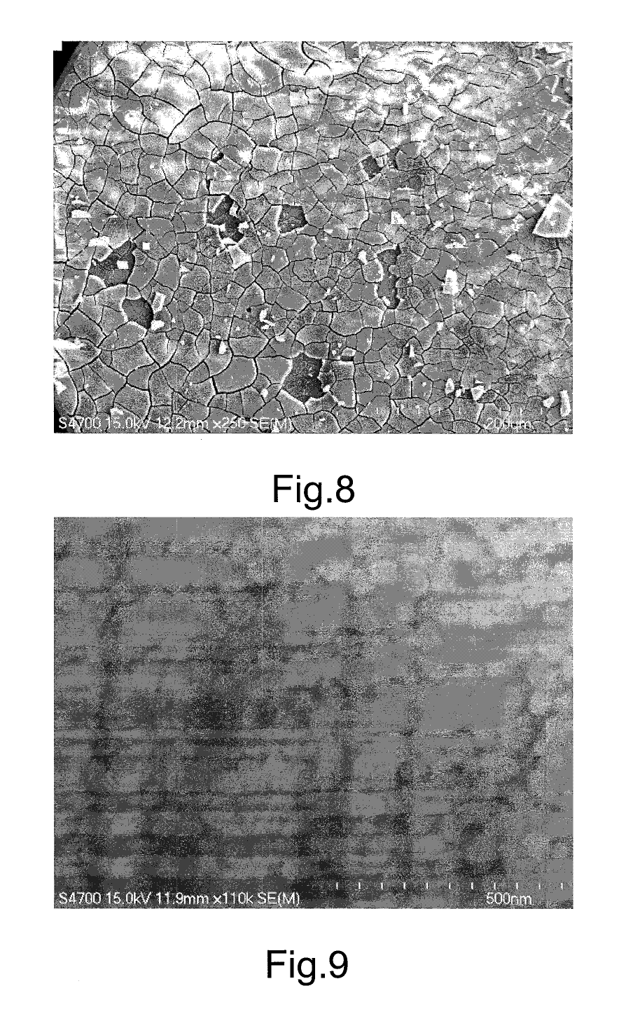

As shown in FIG. 8, the SEM image of sp-PSZ at a magnification of 250× reveals that cracks are generated on the film surface, and the cracks are originated from the calcination process after the formation of the thin film. When the magnification is increased to 100000×, each nanoparticle on the sp-PSZ surface can be observed, as shown in FIG. 9, and the nanoparticle size distribution appears to be uniform. However, cracks are observed on the film surface. The generation of cracks on the film surface may be attributed to the instant removal of the bonding force between the nanoparticles in the calcination, wherein the bonding force is originally derived from the bonding of each nanoparticle with the water molecules and the template molecules.

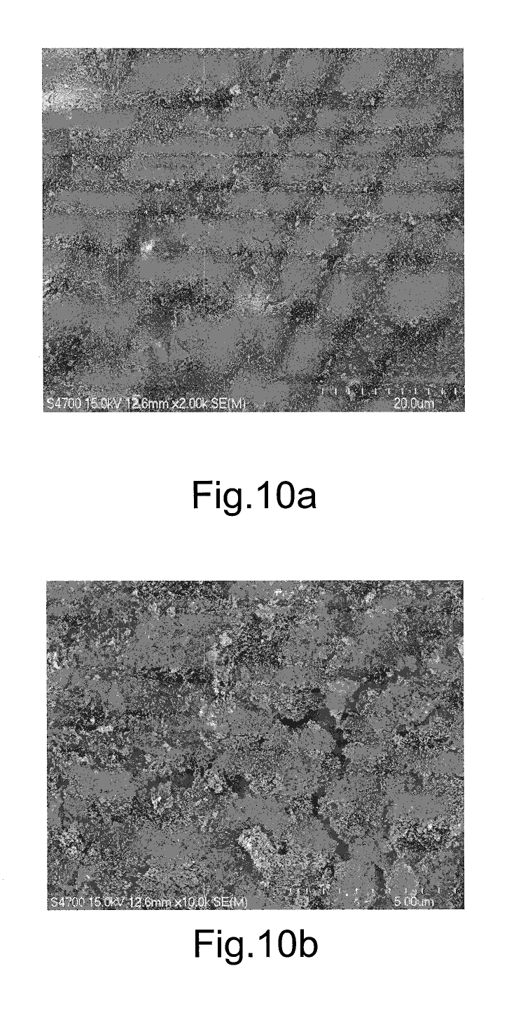

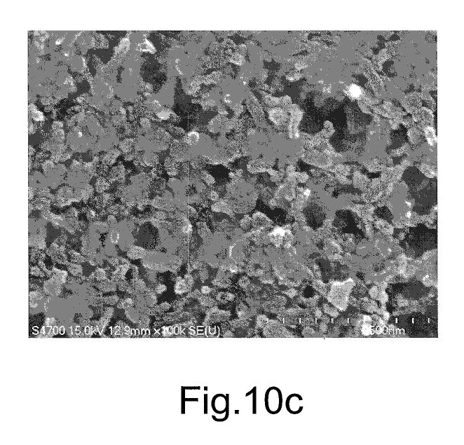

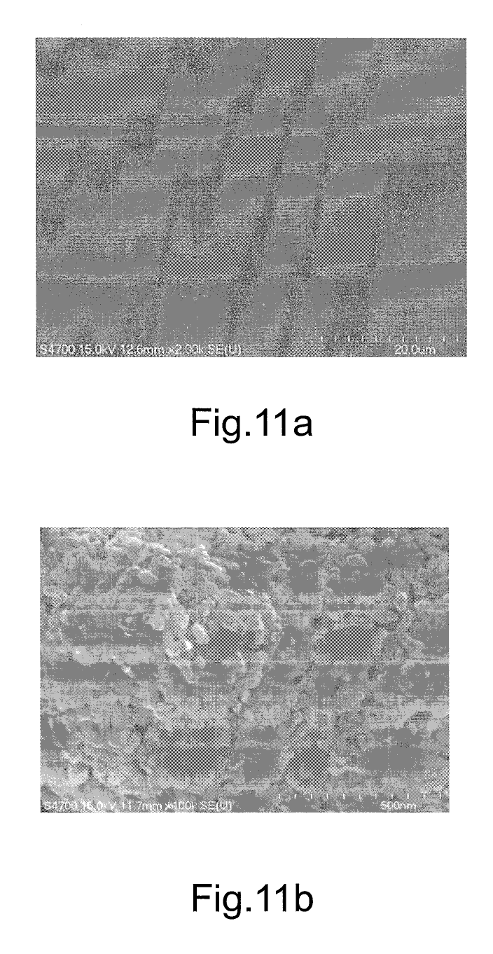

The surface morphology of the sp-MCM and pl-MCM nano-zeolite thin films are also analyzed by SEM and the results are presented in FIGS. 10a-10c and 11a-11b. Although both the sp-MCM and pl-MCM nano-zeolite thin films are constituted with particles of substantially the same size, it is apparent that the particles of the pl-MCM film are more densely packed in an organized terrace-like pattern, while the sp-MCM film displays the presence of gaps, for example, when comparing the SEM results at a magnification of 2000× between the sp-MCM thin film as shown in FIG. 10a and the pl-MCM thin film as shown in FIG. 11a.

### Film Thickness and Film Growing Mechanism

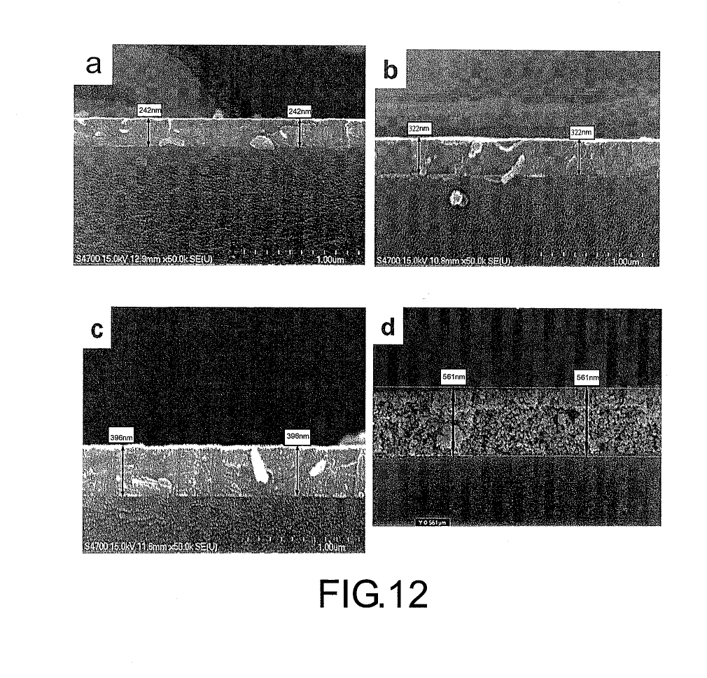

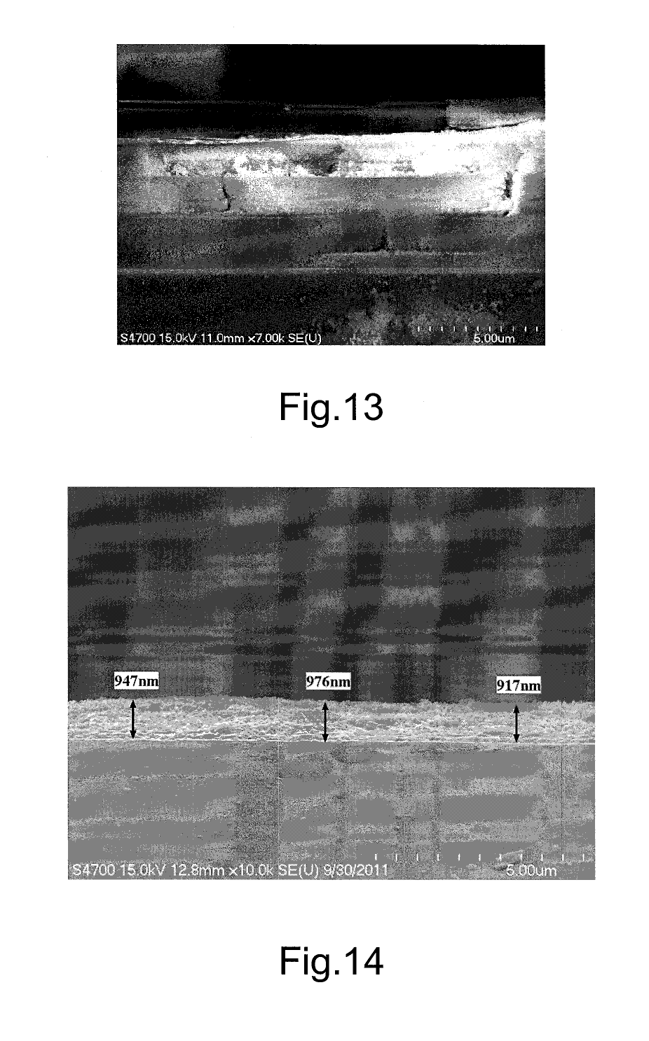

The fabrication of a nano-zeolite thin film (pl-PSZ) is performed in accordance to the process steps as described in Exemplary Embodiment 1. During the thin film formation, field emission-scanning electron microscopy (FE-SEM) (S-4700, Hitachi) is used to observe the cross-section of the zeolite thin films during various time interval of the deposition and to analyze the growing mechanism of the zeolite thin films. The observed results are shown in FIG. 12. Moreover, the pl-MCM zeolite thin film fabricated according to Exemplary embodiment 2 and the multi-layer sp-PSZ fabricated according to Comparative Example 1 are also investigated using FM-SEM, and the observed results are respectively shown in FIGS. 13 and 14.

The micrographs shown in FIG. 12 demonstrate that the thickness of the pl-PSZ thin film at the deposition time of (a) 5 minutes is 240 nm, (b) 15 minutes is 320 nm, (c) 30 minutes is 380 nm, (d) 60 minutes is 561 nm. It can be seen from the SEM micrographs that the thickness of pl-PSZ is determined by the deposition time. The film thickness increases as time increases. Generally speaking, the film thickness may be controlled to between 80 nm to 800 nm for the pl-PSZ film, and the internal pl-PSZ film is densely stacked and stable.

The SEM micrograph of the pl-MCM zeolite thin film as shown in FIG. 13 demonstrate that the thickness of the pl-MCM zeolite thin film at the deposition time of 30 minutes is about 950 nm and rather uniform. In fact, compare to a convention silicalite-1 thin film, a MCM film with a greater thickness, for example, 200 nm˜1000 um, may be formed.

The image of the cross-section of a spin-coated, multi-layer sp-PSZ thin film is shown in FIG. 14. It can observed that the bonding between layers is weak and sp-PSZ thin film appears to have sheet stacked structure. The thickness of the first layer of sp-PSZ is about 0.83 μm, the second and the third layers are respectively 1.83 μm, while the fourth and the fifth layers are respectively 2 μm.

Assuming the film thickness of each layer of the sp-PSZ thin film is influenced by the adhesion force of the substrate, the first layer of the zeolite thin film is mostly affected by the adhesion force of the substrate. Hence, the thickness of the first layer is the smallest. Further, the thickness among layers is not uniform and the bonding strength is not strong, which are some of the drawbacks of a sp-PSZ thin film.

### Surface Tension

The hydrophobicity of pl-PSZ, sp-PSZ and pl-MCM are investigated using a contact angle goniometer (CAM 200) and glycerin (surface tension being 63 dynes/cm) as the solvent.

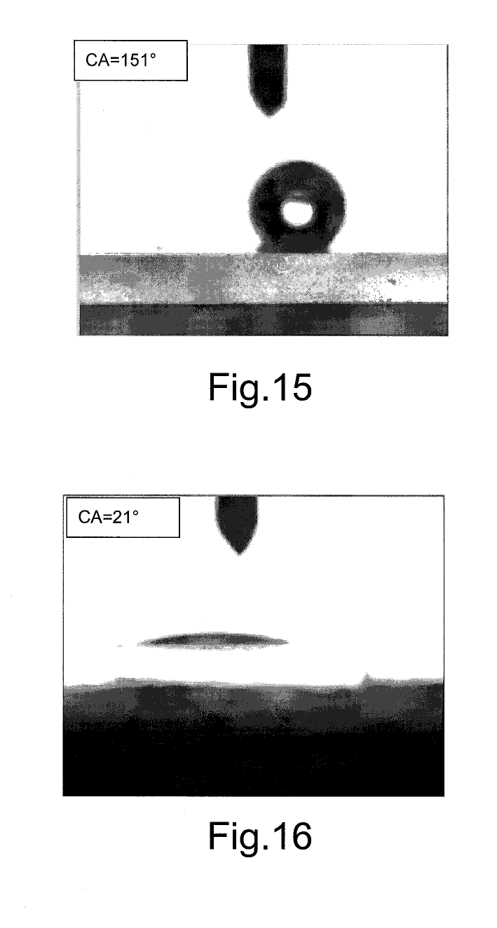

As shown in FIG. 15, the contact angel of pl-PSZ is 151°. When a liquid droplet of glycerin is dispensed on the surface of the pl-PSZ thin film, a nearly spherical liquid bead is formed, indicating that the pl-PSZ thin film is hydrophobic. Referring to FIG. 16, the contact angle of sp-PSZ is 21°, suggesting that surface tension of sp-PSZ is less than that of pl-PSZ. Further, a liquid droplet of glycerin dispensed on the surface of pl-PSZ appears to be flat, indicating that the sp-PSZ thin film is hydrophilic.

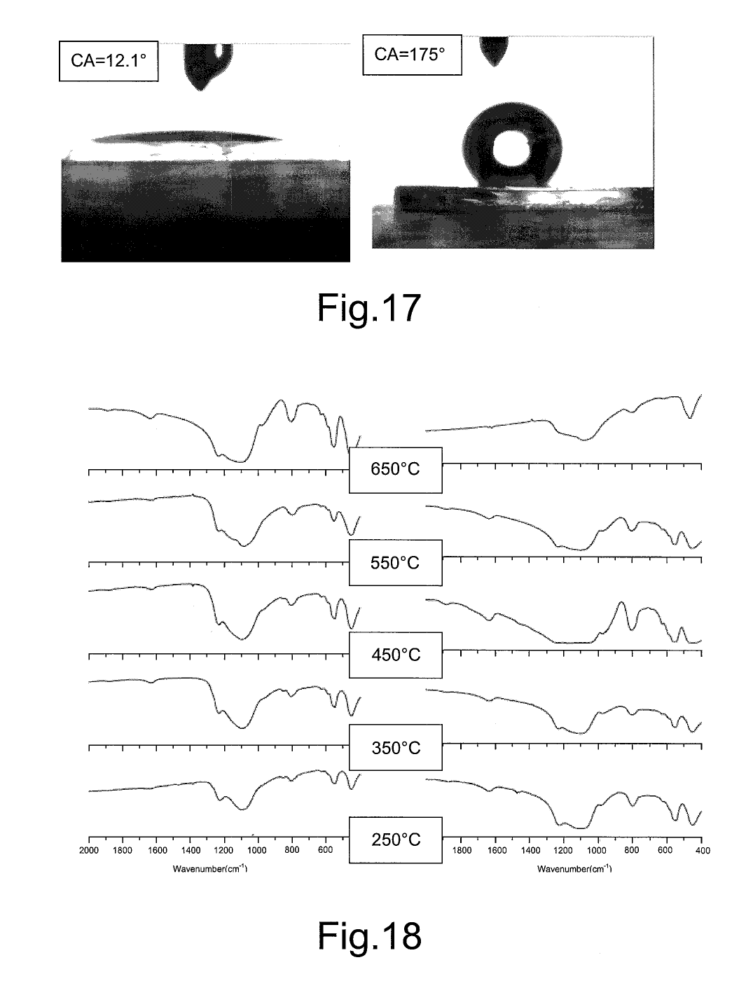

As shown in FIG. 17, the contact angle of a pl-MCM thin film, prior to the surface modification, is 12.1°, due to the presence of more OH groups. However, subsequent to the TMCS surface modification process, the contact angle of the pl-MCM film is 175°, due the replacement of the OH groups with the CH₃ bonds. Moreover, a nearly spherical liquid bead is formed on the pl-MCM film surface subsequent to the TMCS surface treatment process, indicating that the surface-modified pl-MCM thin film is hydrophobic.

### Thermal Stability

FT-IR is used to investigate the thermal stability of the various nano-zeolite thin film samples.

The pl-PSZ thin film and the pl-MCM film are respectively compared with the silicalite-1 powders. The pl-PSZ thin film, the pl-MCM film, and the solvent-free silicalite-1 powers are respectively heated at a temperature between 250° C. to 650° C. More specifically, pl-PSZ, pl-MCM, and the solvent-free silicalite-1 powders are heated at 250° C., 350° C., 450° C., 550° C. and 650° C., respectively for 4 hours prior to the IR measurements.

As shown in FIG. 18, the spectra on the left of the temperature indicator are the IR results of pl-PSZ, while the spectra on the right of the temperature indicator are the IR results of silicalite-1 powders. At the temperature of 650° C., the signal strength of pl-PSZ remains strong, while the signal strength of the silicalite-1 powders appears to have weakened.

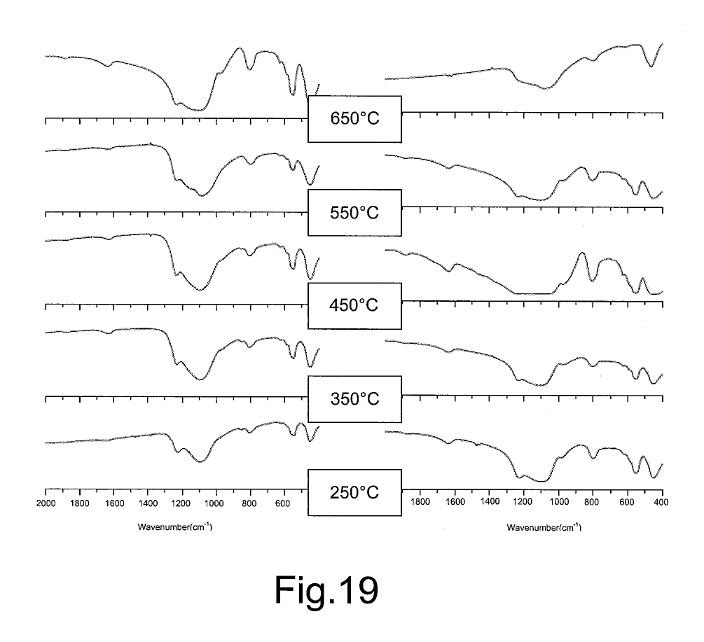

As shown in FIG. 19, the spectra on the left of the temperature indicator are the IR results of pl-MCM, while the spectra on the right of the temperature indicator are the IR results of silicalite-1 powders. Similar to pl-PSZ, the signal strength of pl-MZM remains strong even at the temperature of 650° C.; in contrary, the signal strength of the silicalite-1 powders appears to have weaken at the elevated temperature.

The pl-PSZ film is also compared with the sp-PSZ film. The pl-PSZ film and the sp-PSZ film are respectively heated at a temperature between 250° C. to 650° C. More specifically, IR measurements are performed on the pl-PSZ film and the sp-PSZ films prior to calcination, calcination at a temperate of 550° C. for about four hours, and calcination at a temperature of 600° C. for about six hours, respectively.

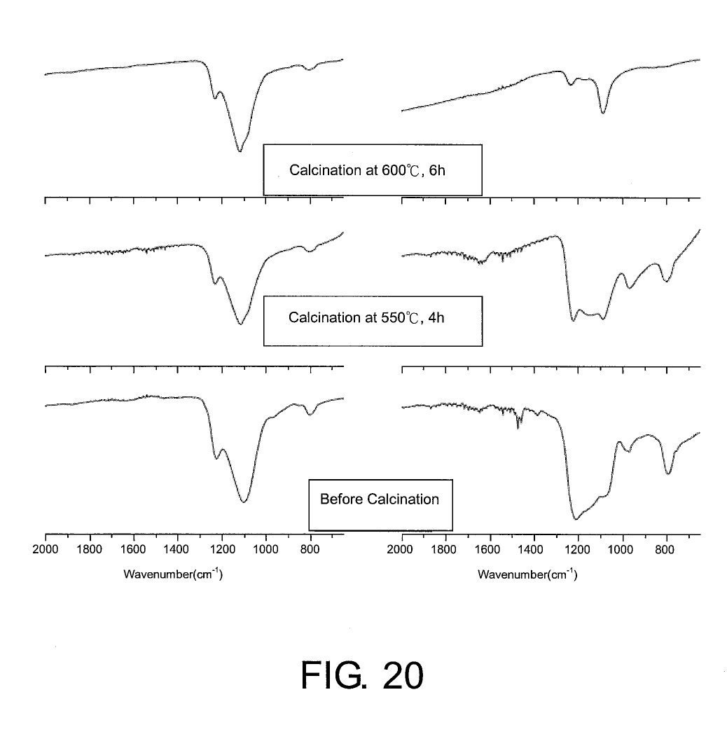

The IR results of the as-prepared zeolite thin films are shown in FIG. 20. The spectra on the left of the temperature indicator are the IR results of pl-PSZ, while the spectra on the right of the temperature indicator are the IR results of sp-PSZ. The signal strength of the functional groups of the pl-PSZ film remains relatively unchanged under the three temperatures, while the signal of the functional groups of the sp-PSZ film placed under the temperature of 600° C. for about 6 hours disappears. These results suggest that the thermal stability of pl-PSZ, which can endure a high temperature of 600° C. is significantly better than that of sp-PSZ.

According to the above comparative analyses, the fabrication of a zeolite thin film by plasma of the invention enhances the thermal stability effect of the zeolite nanoparticles.

### Dielectric Property

An impedance analyzer (LCR meter) (HP-4294A, Hewlett Packard Company) is used to measure the capacitance and the dielectric constant (κ) is calculated based on the capacitance measurement.

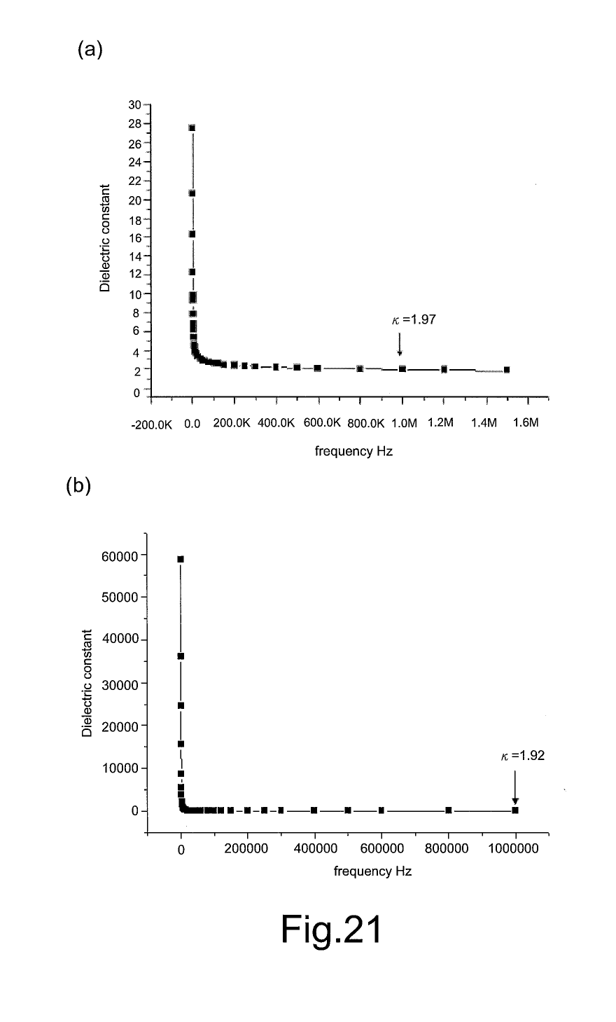

FIG. 21 depicts the dielectric constant results of pl-PSZ (a) and pl-MCM (b), wherein the dielectric constant of pl-PSZ is κ=1.97 (as shown graph (a) of FIG. 21) and the dielectric constant of pl-MCM is κ=1.92 (as shown graph (b) of FIG. 21). Accordingly, the dielectric constant of the nano-zeolite thin film formed according to the fabrication method of the invention can be controlled to below 2. Hence, the nano-zeolite thin film formed according to the fabrication method of the invention satisfy the industry demand on a low dielectric constant film.

According to the above analyses, when comparing the pl-PSZ and pl-MCM of the invention with the conventional sp-PSZ and sp-MCM, the Si—OH content at the pl-PSZ surface or the pl-MCM is lower. Further, the zeolite nanoparticles are more densely packed and stacked, and the zeolite films of the invention are significantly more hydrophobic (CA=151° for pl-PSZ and CA=175° for pl-MCM) and the dielectric constants are lower. In addition, the IR signal strength of pl-PSZ and pl-MCM remain strong prior and subsequent to heating at 550° C., which signifies the thermal stability of pl-PSZ and pl-MCM is better. Accordingly, the present invention provides a fabrication method a low dielectric constant zeolite thin film, not only the fabrication method is environmental friendly, the resulting zeolite thin films possesses desirable properties.

According to the above exemplary embodiments of the invention, by applying a vaporized and ethanol as a dispersant, vaporized droplets containing zeolite nanoparticles are formed. Further subjecting vaporized droplets containing zeolite nanoparticles to a plasma to perform a plasma reaction, the zeolite nanoparticles are deposited on a heated substrate to form with a densely packed thin film with a substantially uniform thickness. Moreover, the templating agents are removed without a calcination process. Hence, not only the fabrication method is simpler, it is also more eco-friendly. In addition, the resulting zeolite thin films are formed with better physical properties, such as lower dielectric constant, higher hydrophobicity, and higher thermal stability. Moreover, the resulting zeolite thin films are formed with highly ordered crystalline structure with pores smaller than integrated circuit features to avoid the electrical interference, for example, interference between transistors.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabrication method of a low dielectric constant (κ) nano-zeolite thin film, the fabrication method comprising:
preparing a zeolite nanoparticle suspension, wherein the zeolite nanoparticle suspension includes a plurality of zeolite nanoparticles suspending in a solvent, and each of the zeolite nanoparticles comprising a plurality of pores with a plurality of templating agents disposed inside the plurality of pores;
performing a heat treatment on a substrate to form a heated substrate;
vaporizing the zeolite nanoparticle suspension to form a plurality of vaporized droplets containing the zeolite nanoparticles;
delivering the plurality of vaporized droplets containing the plurality of zeolite nanoparticles into a plasma; and
performing a plasma reaction for obtaining a plurality of plasma treated zeolite nanoparticles and depositing the plurality of plasma treated zeolite nanoparticles on the heated substrate, while removing the plurality of templating agents to form the low κnano-zeolite thin film with a dielectric constant less than 2.

2. The fabrication method of claim 1, wherein the step of performing the heat treatment on the substrate comprises heating the substrate to about 175° C. to about 300° C.

3. The fabrication method of claim 2, wherein the plurality of the zeolite nanoparticle suspension is vaporized using ethanol or water as a dispersant.

4. The fabrication method of claim 1, after the step of depositing the plurality of plasma treated zeolite nanoparticles on the heated substrate, a preliminary zeolite thin film is formed and a surface modification process is performed on the preliminary zeolite thin film.

5. The fabrication method of claim 4, wherein the surface modification process comprises altering a hydrophobicity of a surface of the preliminary zeolite thin film.

6. The fabrication method of claim 4, wherein the surface modification process comprises immersing in the preliminary zeolite thin film in trimethylchlorosilane (TMCS), followed by performing a heat treatment at 60° C. for about 15 minutes.

7. The fabrication method of claim 1, wherein the low κnano-zeolite thin film comprises a MCM-41 zeolite thin film having the dielectric constant of about 1.92.

8. The fabrication method of claim 1, wherein the low κnano-zeolite thin film comprises a silicalite-1 zeolite thin film having a dielectric constant of about 1.97.

9. The fabrication method of claim 1, wherein the plasma is generated by applying a pulse type alternating current voltage of 60V to 90V.

10. The fabrication method of claim 1, wherein the low nano-zeolite thin film is formed with a thickness of about 80nm to about 1 um.

11. A low dielectric constant nano-zeolite thin film having a dielectric constant of less than 2, a hydrophobicity (CA) greater than 150, a thermal stability of about 600° C., and a surface of the low dielectric constant nano-zeolite thin film is constituted with zeolite nanoparticles that are densely stacked in an organized pattern.

12. A low dielectric constant (κ) nano-zeolite thin film, wherein a method of fabricating the low dielectric constant nano-zeolite thin film comprises:
preparing a zeolite nanoparticle suspension, wherein the zeolite nanoparticle suspension includes a plurality of zeolite nanoparticles suspending in a solvent, and each of zeolite nanoparticles comprising a plurality of pores with a plurality of templating agents disposed inside the plurality of pores;
heating a substrate to form a heated substrate;
vaporizing the zeolite nanoparticle suspension to form a plurality of vaporized droplets containing the zeolite nanoparticles;
carrying the plurality of vaporized droplets containing the plurality of zeolite nanoparticles into a plasma to perform a plasma reaction for obtaining of a plurality of plasma-treated zeolite nanoparticles; and
depositing the plurality of plasma-treated zeolite nanoparticle on the heated substrate to form the low κnano-zeolite thin film with the templating agents removed and with a dielectric constant of less than 2, a hydrophobicity (CA) greater than 150, a thermal stability of about 600° C., and a surface of the low dielectric constant nano-zeolite thin film constituted with zeolite nanoparticles that are densely stacked in an organized pattern.

13. The low κnano-zeolite thin film of claim 12, wherein after the step of depositing the plurality of plasma treated zeolite nanoparticles on the heated substrate, a preliminary zeolite thin film is formed and a surface modification process is performed on the preliminary zeolite thin film.

14. The low κnano-zeolite thin film of claim 13, wherein the surface modification process comprises increasing a hydrophobicity of the preliminary zeolite thin film.

15. The low κnano-zeolite thin film of claim 14, where the hydrophobicity of the low κnano-zeolite thin film is about 175 and a dielectric constant of the low κnano-zeolite thin film is less than 1.95.

16. The low κnano-zeolite thin film of claim 13, wherein the dielectric constant of the low κnano-zeolite thin film is less than or equal to 1.97.

17. The low κnano-zeolite thin film of claim 13, wherein the templating agents of the low κnano-zeolite thin film are removed during the plasma reaction and the deposition of the plurality of plasma-treated zeolite nanoparticles on the heated substrate at about 175° C. to about 300° C.

18. The low κnano-zeolite thin film of claim 13, the zeolite nanoparticle suspension is vaporized using ethanol or water as a dispersant.

19. The low κnano-zeolite thin film of claim 13, wherein a surface of the low dielectric constant zeolite nanoparticle thin film is constituted with zeolite nanoparticles that are densely stacked in an organized pattern.
